(19) United States
(12) Patent Application Publication
(10) Pub. No.: US 2013/0302592 A1
(43) Pub. Date: Nov. 14, 2013

(54) METHOD FOR GROWTH OF CARBON NANOFLAKES AND CARBON NANOFLAKE STRUCTURE

(71) Applicant: KOREA INSTITUTE OF SCIENCE AND TECHNOLOGY, Seoul (KR)

(72) Inventors: Wook Seong LEE, Seoul (KR); Hak Joo LEE, Incheon (KR); Young Joon BAIK, Seoul (KR); Jong Keuk PARK, Seoul (KR)

(73) Assignee: KOREA INSTITUTE OF SCIENCE AND TECHNOLOGY, Seoul (KR)

(21) Appl. No.: 13/684,291

(22) Filed: Nov. 23, 2012

(30) Foreign Application Priority Data
May 9, 2012 (KR) 10-2012-0049140

(51) Int. Cl. C23C 16/26

(52) U.S. Cl. CPC C23C 16/26; Y10S 977/842; B82Y 40/00
USPC 428/323; 427/249.1; 977/842; 977/734; 977/779

(57) ABSTRACT

A method for growing carbon nanoflakes includes inducing partial etching of graphene layers of carbon nanotubes through an adequate composition of precursor gases, CH₄, H₂ and Ar, while allowing carbon nanoflakes to grow at the etched site in a plane-like shape. A carbon nanoflake structure is formed by the same method. The method for growing carbon nanoflakes includes: providing a silicon substrate having carbon nanotubes; and growing carbon nanoflakes on the carbon nanotubes through a chemical vapor deposition process using a mixed gas of CH₄, H₂ and Ar as a precursor. During the chemical vapor deposition process, the mixed gas of CH₄, H₂ and Ar is in an atmosphere with excess Ar, graphene layers forming the carbon nanotubes are etched partially under the atmosphere with excess Ar, and graphene layers of carbon nanoflakes are grown at the etched site.

### CROSS-REFERENCE TO RELATED APPLICATION

This application claims priority to Korean Patent Application No. 10-2012-0049140, filed on May 9, 2012, and all the benefits accruing therefrom under 35 U.S.C. §119, the contents of which in its entirety are herein incorporated by reference.

### BACKGROUND

1. Field

Embodiments relate to a method for growing carbon nanoflakes and a carbon nanoflake structure formed thereby. More particularly, the embodiments relate to a method for growing carbon nanoflakes, including inducing partial etching of graphene layers of carbon nanotubes through an adequate composition of precursor gases, CH₄, H₂ and Ar, while allowing carbon nanoflakes to grow at the etched site in a plane-like shape, as well as to a carbon nanoflake structure formed by the same method.

2. Description of the Related Art

Carbon nanomaterials have potential applicability in field emission devices, electronic devices, optoelectronic devices, gas and energy storage devices, or the like. Particularly, carbon nanoflakes (CNFs) and carbon nanowalls (CNWs) are carbon nanomaterials having a two-dimensional structure, and have excellent physical and chemical properties, such as a high specific surface area and high hydrophobicity. Thus, they are applicable to large-area field emission sources, gas sensors, high-capacity capacitors, or the like.

Carbon nanoflakes may be synthesized through various methods. Since carbon nanoflakes have been synthesized through an evaporation process using direct current arc discharge (Ando Y., Zhao X., Ohkohchi M., Production of petal-like graphite sheets by hydrogen arc discharge, Carbon, 1997: 35(1): 153-8), attempts have been made to synthesize carbon nanoflakes by using plasma assisted chemical vapor deposition (PACVD), to which DC plasma, helicon plasma or microwave plasma is applied individually, and hot filament CVD (HFCVD). In addition, various types of catalysts, growing conditions and substrates have been applied as conditions for synthesis independently from deposition methods. Nevertheless, growth mechanisms of carbon nanoflakes still have not been clearly understood.

### SUMMARY

An aspect of the present disclosure is directed to providing a method for growing carbon nanoflakes, including inducing partial etching of graphene layers of carbon nanotubes through an adequate composition of precursor gases, CH₄, H₂ and Ar, while allowing carbon nanoflakes to grow at the etched site in a plane-like shape, as well as to a carbon nanoflake structure formed by the same method.

According to an embodiment, a method for growing carbon nanoflakes includes: providing a silicon substrate having carbon nanotubes; and growing carbon nanoflakes on the carbon nanotubes through a chemical vapor deposition process using a mixed gas of CH₄, H₂ and Ar as a precursor. During the chemical vapor deposition process, the mixed gas of CH₄, H₂ and Ar may be in an atmosphere with excess Ar, graphene layers forming the carbon nanotubes may be etched partially under the atmosphere with excess Ar, and graphene layers of carbon nanoflakes may be grown at the etched site.

The mixed gas of CH₄, H₂ and Ar may have a composition of CH₄:H₂:Ar=1:4-15:84-95. In addition, the carbon nanotubes may be multi-walled carbon nanotubes (MWCNTs) or single-walled carbon nanotubes (SWCNTs).

The operation of providing a silicon substrate having carbon nanotubes may include: preparing a methanol solution in which carbon nanotubes are dispersed; casting the methanol solution in which carbon nanotubes are dispersed onto a silicon substrate; and drying the substrate to evaporate methanol.

According to an embodiment, a carbon nanoflake structure includes carbon nanotubes provided on a silicon substrate, and carbon nanoflakes grown on the carbon nanotubes, wherein the carbon nanoflakes are grown through a chemical vapor deposition process using a mixed gas of CH₄, H₂ and Ar in an atmosphere with excess Ar as a precursor. During the chemical vapor deposition process, graphene layers forming the carbon nanotubes may be etched partially under an atmosphere with excess Ar, and graphene layers of carbon nanoflakes may be grown at the etched site. The mixed gas of CH₄, H₂ and Ar may have a composition of CH₄:H₂:Ar=1:4-15:84-95.

### BRIEF DESCRIPTION OF THE DRAWINGS

The above and other aspects, features and advantages of the disclosed exemplary embodiments will be more apparent from the following detailed description taken in conjunction with the accompanying drawings in which:

FIG. 1 shows a scanning electron microscopy (SEM) image of the microstructure of multi-walled carbon nanotubes (MWCNTs) dispersed on a silicon substrate (portion (a)), and SEM images of carbon nanoflakes formed on the MWCNTs (portions (b) and (c));

FIG. 2 shows SEM images illustrating a silicon substrate on which nanocrystalline diamond particles are dispersed before deposition (portion (a)) and after deposition (portion (d)), SEM images illustrating a silicon substrate on which mesoporous carbon particles are dispersed before deposition (portion (b)) and after deposition (portion (e)), and SEM images illustrating a silicon substrate on which single-walled carbon nanotubes (SWCNTs) are dispersed before deposition (portion (c)) and after deposition (portion (f);

FIG. 3 shows the Raman spectra of the samples as shown in FIG. 2 after deposition;

FIG. 4 shows a transmission electron microscopy (TEM) image illustrating products grown on a substrate on which MWCNTs are dispersed under an atmosphere with excess Ar;

FIG. 5 shows a TEM image of carbon nanoflakes grown on a substrate on which MWCNTs are dispersed (portion (a)), a selected area electron diffraction (SAED) pattern thereof (portion (b)), TEM images of an individual carbon nanoflake (portions (c), (d) and (e)), and a TEM image of MWCNTs (portion (f);

FIG. 6 shows SEM images illustrating MWCNTs before and after a ramp stage (portions (a) and (b), respectively); and

FIG. 7 shows a schematic side view of partially etched MWCNTs (portion (a)), a schematic sectional view of partially etched MWCNTs (portion (b)), a schematic view illustrating carbon nanoflakes grown at the etched site of portion (b) (portions (c) and (d)), and a schematic view illustrating carbon nanoflakes grown at the etched site in the presence of partially etched SWCNTs (portion (e)).

### DETAILED DESCRIPTION

Exemplary embodiments now will be described more fully hereinafter with reference to the accompanying drawings, in which exemplary embodiments are shown

According to an embodiment, carbon nanoflakes (CNFs) may be formed on carbon nanotubes (CNTs). The carbon nanoflakes are formed through a chemical vapor deposition process, and a mixed gas of CH₄, H₂ and Ar is used as a precursor gas.

The mixed gas of CH₄, H₂ and Ar serves to carry out partial etching and removal of graphene layers forming carbon nanotubes, and functions as a carbon source for the carbon nanoflakes to be grown on the site from which the graphene layers are etched out.

It is required for carbon nanotubes to be etched adequately to allow growth of carbon nanoflakes. As used herein, the expression ‘etched adequately’ means that graphene layers forming carbon nanotubes are etched partially to such a degree that the graphene layers retain dangling bonds. The dangling bonds of the graphene layers serve as growth nuclei for carbon nanoflakes.

To perform partial etching of the graphene layers of carbon nanotubes, it is required to control the composition of a mixed gas of CH₄, H₂ and Ar. When the mixed gas of CH₄, H₂ and Ar is in an atmosphere with excess H₂, carbon nanotubes may be etched excessively due to H₂, thereby making it difficult to grow carbon nanoflakes. On the other hand, when the mixed gas is in an atmosphere with excess Ar, excessive etching of carbon nanotubes is inhibited. In other words, it is possible to induce partial etching of carbon nanotubes so that carbon nanoflakes may be grown.

To allow growth of carbon nanoflakes, the mixed gas of CH₄, H₂ and Ar may have a composition of CH₄:H₂:Ar=1:4-15:84-95. When H₂ is present in an amount greater than 15 vol %, carbon nanotubes may be etched excessively. On the other hand, when Ar is present in an amount greater than 95 vol %, carbon atom sources become insufficient, thereby making it difficult to grow carbon nanoflakes.

Carbon nanotubes are dispersed and fixed on a silicon substrate. Particular examples of carbon nanotubes that may be used herein include both multi-walled carbon nanotubes (MWCNTs) and single-walled carbon nanotubes (SWCNTs). MWCNTs have a plurality of graphene layers wound into a cylindrical shape, while SWCNTs have a single graphene layer wound into a cylindrical shape.

While MWCNTs and SWCNTs have a cylindrical shape, carbon nanoflakes formed thereon have a plane-like shape with no curved surface. This is because internal stress applied to carbon nanotubes is released due to the partial etching of carbon nanotubes. The internal stress applied to the inside of carbon nanotubes so that they have a cylindrical shape is released by the partial etching of graphene layers, and then graphene layers of carbon nanoflakes are grown on the etched site from which the internal stress is released. In this manner, carbon nanoflakes grown in a plane-like shape.

According to an embodiment, since the carbon nanoflakes grow on such partially etched graphene layers of carbon nanotubes, it is not possible to grow carbon nanoflakes on nanocrystalline diamond or mesoporous carbon having no graphene layer structure.

Meanwhile, when growing carbon nanoflakes according to an embodiment, no additional catalyst is required for the growth of carbon nanoflakes and no additional plasma application is required for stimulating reaction. According to an embodiment, carbon nanoflakes may be grown on carbon nanotubes through hot filament CVD (HFCVD).

The examples and experiments will now be described together with the results of experiments to illustrate the method for growing carbon nanoflakes disclosed herein.

### EXAMPLE 1

### Growth of Carbon Nanoflakes

MWCNTs having a purity of 95 wt % or more and available from Carbon Nano-material Technology Co., Ltd. are dispersed in methanol and treated in an ultrasonic bath for 30 minutes. Then, the methanol solution containing the MWCNTs dispersed therein is applied by drop-casting to a p-type silicon substrate grown in the direction of (100) and having a size of 1×1 inch², followed by drying at room temperature for 12 hours.

Then, the substrate is mounted to the substrate holder of a hot filament CVD (HFCVD) system. The substrate holder is provided on a water-cooling block. A carbonized tungsten filament with a diameter of 0.3 mm is provided on the top of the substrate holder, and the substrate is spaced apart from the tungsten filament by about 10 mm. The reaction chamber maintains a vacuum state of ˜10⁻³ Torr before deposition. As a mixed gas of CH₄, H₂ and Ar is introduced to the chamber, the pressure in the chamber is increased. When the chamber reaches an internal pressure of 7.5 Torr, the current applied to the tungsten filament is increased from 0 to a reaction condition of 8.5 A. The time required to increase the current to 8.5 A is 4 minutes.

While the chamber is maintained continuously at an internal pressure of 70.5 Torr, deposition is carried out for 2 hours. During deposition, the tungsten filament is measured to have a temperature of 2400° C. After measuring the deposition temperature with a thermocouple provided on the substrate holder, it is observed that the deposition temperature is 840° C.

When carrying out a deposition process, the mixed gas of CH₄, H₂ and Ar is set to a total feed flux of 100 sccm (standard cubic centimeter per minute). While the flux of CH₄ is fixed at 1 sccm, the flux of H₂ and that of Ar are varied. In other words, the flux of CH₄/H₂/Ar is varied within a range of 1/84/15 to 1/15/84.

To investigate the growth mechanism of carbon nanoflakes, silicon substrates, on which nanocrystalline diamond (diameter 5 nm), mesoporous carbon (available from Sigma Aldrich Co.) or SWCNTs (available from Carbon Nano-material Technology, Co. Ltd.) are dispersed individually, are subjected to the same processing conditions as the substrate on which MWCNTs are dispersed to carry out deposition.

### EXAMPLE 2

### Results

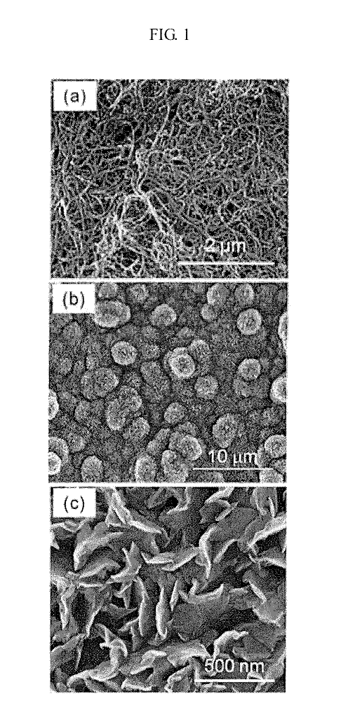

FIG. 1 shows a scanning electron microscopy (SEM) image of the microstructure of multi-walled carbon nanotubes (MWCNTs) dispersed on a silicon substrate, in portion (a). When a mixed gas of CH₄(1-5 vol %) with H2 (95-99 vol %) free from Ar gas is supplied at a flux of 100 sccm, the MWCNTs on the substrate are etched out totally. When a mixed gas having a composition varied within a range of 1/84/15-1/30/69 (CH₄/H₂/Ar) is supplied at a total flux of 100 sccm, the results are similar to the above case using a mixed gas free from Ar gas. On the contrary, when Ar gas flux is increased to 84 (i.e., when the composition of CH₄/H₂/Ar is 1/15/84), carbon nanoflakes are observed over the whole surface of the substrate (see, portions (b) and (c) of FIG. 1). Further, such carbon nanoflakes are observed in all samples having an area of several square millimeters or more. After carrying out further experiments, it is observed that carbon nanoflakes are formed until Ar gas flux is 95. When Ar gas flux exceeds 95, MWCNT etching is inhibited but carbon nanoflake formation becomes hard due to the lack of carbon atom sources.

Under an atmosphere with excess hydrogen atoms, carbon (SP²) is etched with ease. Similarly, even under a low content of Ar gas, carbon (SP²) is etched. Only under an atmosphere with excess Ar, carbon nanoflakes are formed sufficiently. This suggests that such an atmosphere with excess Ar inhibits carbon (SP²) of MWCNTs from being etched, while facilitating nucleation of carbon nanoflakes.

The mixed gas composition (CH₄/H₂/Ar=1/15/84) that allows formation of carbon nanoflakes on a silicon substrate on which MWCNTs are dispersed is also applied to silicon substrates on which nanocrystalline diamond, mesoporous carbon and SWCNTs are dispersed individually. The same HFCVD process as described above is also applied.

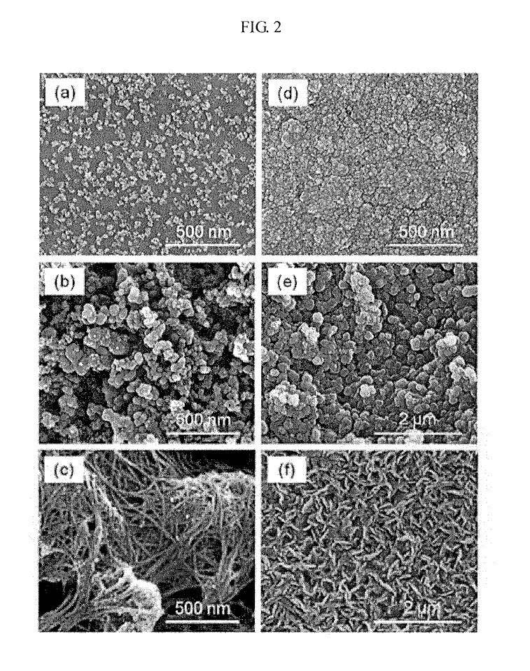

FIG. 2 shows SEM images illustrating a silicon substrate on which nanocrystalline diamond particles are dispersed before deposition (portion (a)) and after deposition (portion (d)). Referring to portion (d) of FIG. 2, it is observed that a general nanocrystalline diamond thin film is formed on the substrate. Portions (b) and (e) of FIG. 2 show SEM images of a silicon substrate on which mesoporous carbon particles are dispersed, before deposition and after deposition, respectively. No significant change is observed before and after deposition. In other words, carbon nanoflakes are not formed on a silicon substrate on which mesoporous carbon is dispersed. On the contrary, portions (c) and (f) of FIG. 2 show SEM images of a silicon substrate on which SWCNTs are dispersed, before deposition and after deposition, respectively. As can be seen from portion (f) of FIG. 2, carbon nanoflakes are grown on the substrate.

As can be seen from the above results, carbon nanoflakes are grown on a substrate on which MWCNTs or SWCNTs are dispersed. Based on this, it is believed that the growth mechanism of carbon nanoflakes is related closely with CNT structures. Meanwhile, SWCNTs or SWCNTs have SP² carbon atoms aligned in a honeycomb-like form.

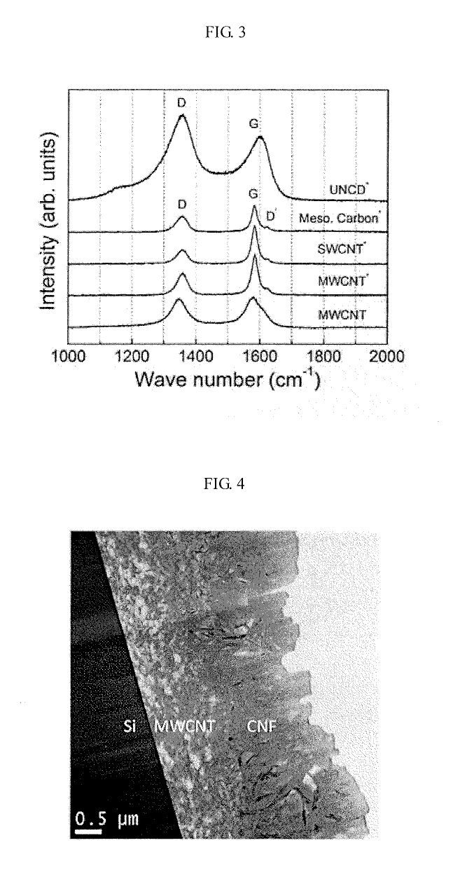

FIG. 3 shows the Raman spectra of the samples as shown in FIG. 2 after deposition. For all the samples of FIG. 2, D (1350 cm⁻¹), G (1580 cm⁻¹) and D′ (1630 cm⁻¹) bands are observed. In the case of portion (d) of FIG. 2 in which a nanocrystalline diamond thin film is deposited, a peak is observed at 1150 cm⁻¹. It is proved that the peak results from polyacetylene present in a grain boundary of nanocrystalline diamond.

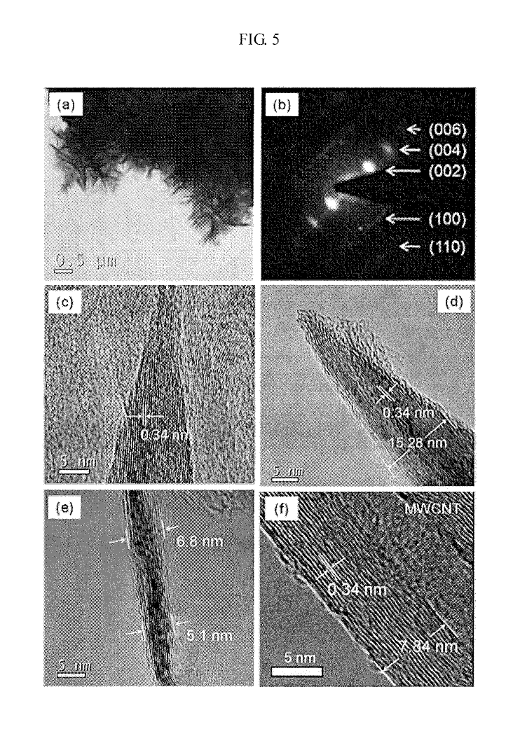

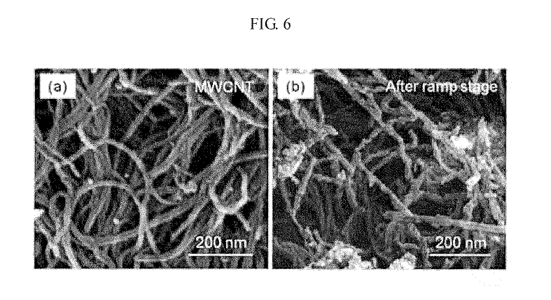

FIG. 4 shows a transmission electron microscopy (TEM) image illustrating products grown on a substrate on which MWCNTs are dispersed under an atmosphere with excess Ar. FIG. 4 clearly proves the growth of carbon nanoflakes. FIG. 5 shows a TEM image of carbon nanoflakes grown on a substrate on which MWCNTs are dispersed (portion (a)), and a selected area electron diffraction (SAED) pattern thereof (portion (b)). FIG. 5 also shows TEM images of an individual carbon nanoflake (potions (c), (d) and (e)), and a TEM image of MWCNTs (portion (f). Referring to portions (c)-(f) of FIG. 5, the space between the graphene layers of carbon nanoflakes has a shape similar to the shape of the space between the graphene layers of MWCNTs. In addition, it is observed that the number of the graphene layers of carbon nanoflakes in portions (d) and (e) of FIG. 5 is different slightly from the number of the graphene layers of MWCNTs in portion (f) of FIG. 5. This is related closely with the growth mechanism of carbon nanoflakes as described in more detail hereinafter.

To investigate the growth mechanism of carbon nanoflakes, MWCNTs are observed after a ramp stage is completed. As used herein, the term ‘ramp stage’ refers to the initial stage of growth from the time at which point electric current is applied to a tungsten filament to the time at which point a target current is applied. According to some embodiments, the term ‘ramp stage’ refers to a 4-minute stage during which a current of 0 to 8.5 A is applied. FIG. 6 shows SEM images illustrating MWCNTs before and after a ramp stage in portions (a) and (b), respectively. Referring to portion (b) of FIG. 6, it can be seen that MWCNTs are etched partially after the completion of the ramp stage.

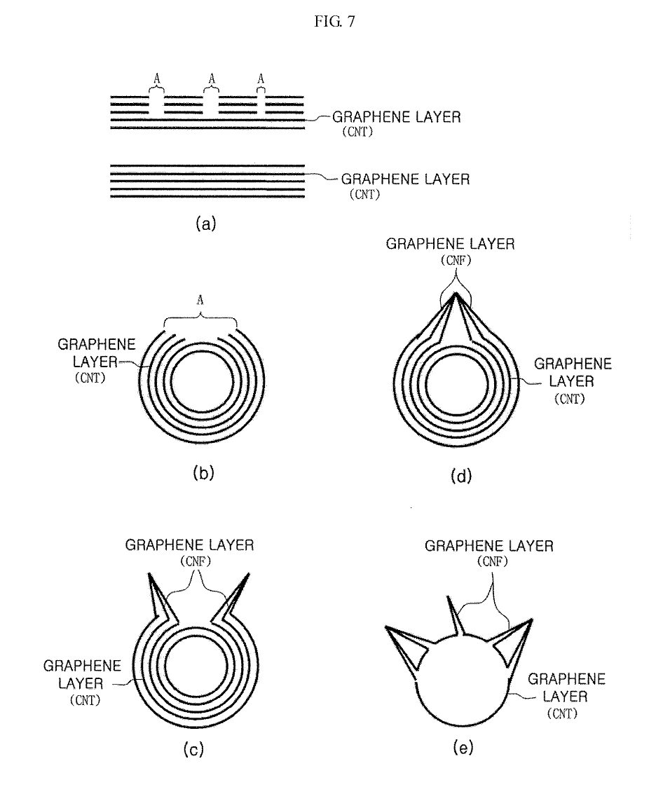

The MWCNTs etched partially after the ramp stage, like in portion (b) of FIG. 6, may be shown schematically in portions (a) and (b) of FIG. 7. FIG. 7 shows a schematic side view of partially etched MWCNTs in portion (a), and a schematic sectional view of partially etched MWCNTs in portion (b). In portions (a) and (b) of FIG. 7, the MWCNTs have a plurality of graphene layers, and a site where a bond is broken in each graphene layer is etched to provide an etched site A.

Such partial etching of MWCNTs results from hydrogen atoms, and a dangling bond is formed at the etched site. The dangling bond functions as a growth nucleus for carbon nanoflakes, and carbon bonding and growth are performed at the dangling bond. In other words, carbon nanoflakes are grown at each etched site of MWCNT graphene layers with a direction of growth parallel to the MWCNT graphene layers.

FIG. 7 also shows a schematic view of carbon nanoflakes grown at the etched site A in portion portions (c) and (d). Portion (c) shows that carbon nanoflakes are grown individually at each point of the etched site in portion (b) of FIG. 7. Portion (d) shows that carbon nanoflakes are grown individually at each point of the etched site in portion (b) of FIG. 7 to form a bonding at one point. Referring to portion (c) of FIG. 7, the number of graphene layers of carbon nanoflakes grown by the individual growth of carbon nanoflakes at each point of the etched site is less than the number of graphene layers of MWCNTs. Referring to portion (d) of FIG. 7, since the carbon nanoflakes are grown at each point of the etched site to form a bonding, the number of graphene layers of the grown carbon nanoflakes may be greater than the number of graphene layers of MWCNTs.

Portion (e) of FIG. 7 shows a schematic view of carbon nanoflakes grown at the etched site in the presence of partially etched SWCNTs. Similarly to MWCNTs, carbon nanoflakes may be grown at the etched site of graphene layers of SWCNTs, as determined by the results of portion (f) of FIG. 2.

The fact that growth of carbon nanoflakes is allowed not only on MWCNTs but also on SWCNTs is one of the most important findings. Carbon nanotubes have graphene layers wound into a cylindrical shape, and thus are subjected to internal stress. As mentioned above, the partial etching of CNTs breaks a connected structure of graphene layers to release internal stress, which, in turn, allows the carbon nanoflakes grown at the etched site of CNT graphene layers to grow in a plane-like shape having no curved surface. On the contrary, it is a matter of course that such a CNT-based carbon nanoflake growth mechanism cannot be applied to nanocrystalline diamond and mesoporous carbon having no graphene structure.

The method for growing carbon nanoflakes and the carbon nanoflake structure obtained thereby provide the following effects.

The method includes inducing partial etching of carbon nanotubes under an atmosphere with excess Ar, and thus it is possible to grow carbon nanoflakes easily with no need for application of an additional catalyst or plasma.

While the exemplary embodiments have been shown and described, it will be understood by those skilled in the art that various changes in form and details may be made thereto without departing from the spirit and scope of the present disclosure as defined by the appended claims.

What is claimed is:

1. A method for growing carbon nanoflakes, comprising:
providing a silicon substrate having carbon nanotubes; and
growing carbon nanoflakes on the carbon nanotubes through a chemical vapor deposition process using a mixed gas of CH₄, H₂ and Ar as a precursor,
wherein the mixed gas of CH₄, H₂ and Ar is in an atmosphere with excess Ar during the chemical vapor deposition process, graphene layers forming the carbon nanotubes are etched partially under the atmosphere with excess Ar, and graphene layers of carbon nanoflakes are grown at the etched site.

2. The method for growing carbon nanoflakes according to claim 1, wherein the mixed gas of CH₄, H₂ and Ar has a composition of CH₄:H₂:Ar=1:4-15:84-95.

3. The method for growing carbon nanoflakes according to claim 1, wherein the carbon nanotubes are multi-walled carbon nanotubes (MWCNTs) or single-walled carbon nanotubes (SWCNTs).

4. The method for growing carbon nanoflakes according to claim 1, wherein the providing the silicon substrate having carbon nanotubes comprises:
preparing a methanol solution in which carbon nanotubes are dispersed;
casting the methanol solution in which carbon nanotubes are dispersed onto the silicon substrate; and
drying the substrate to evaporate methanol.

5. A carbon nanoflake structure, comprising:
carbon nanotubes provided on a silicon substrate; and
carbon nanoflakes grown on the carbon nanotubes,
wherein the carbon nanoflakes are grown through a chemical vapor deposition process using a mixed gas of CH₄, H₂ and Ar in an atmosphere with excess Ar as a precursor,
wherein graphene layers forming the carbon nanotubes are etched partially under an atmosphere with excess Ar during the chemical vapor deposition process, and graphene layers of carbon nanoflakes are grown at the etched site, and
wherein the mixed gas of CH₄, H₂ and Ar has a composition of CH₄:H₂:Ar=1:4-15:84-95.
